(19) United States
(12) Patent Application Publication
(10) Pub. No.: US 2025/0054816 A1
(43) Pub. Date: Feb. 13, 2025

(54) METHODS FOR FABRICATING A DIODE WAFER AND A WAFER TO BE PROCESSED

(71) Applicants: SHIH-CHING YANG, HSINCHU COUNTY (TW); TE-SUNG TU, HSINCHU COUNTY (TW); KSEC CO., LTD., HSINCHU COUNTY (TW)

(72) Inventors: SHIH-CHING YANG, HSINCHU COUNTY (TW); TE-SUNG TU, HSINCHU COUNTY (TW)

(21) Appl. No.: 18/798,924

(22) Filed: Aug. 9, 2024

(30) Foreign Application Priority Data
Aug. 11, 2023 (TW) 112130269

(51) Int. Cl. H01L 21/66; H01L 29/861

(52) U.S. Cl. CPC H01L 22/12; H01L 29/861

(57) ABSTRACT

Methods for fabricating diode wafers and wafers to be processed process raw wafers sliced from an ingot and determines whether the raw wafers meet a fabrication specification. When the determined result is yes, the raw wafer is used as a high-grade raw wafer. When the determined result is no, the raw wafers are used as low-grade raw wafers. Next, the method calculates the ratio of the number of low-grade raw wafers with problems related to crystal oriented pits to the number of all low-grade raw wafers and determines whether the ratio is greater than a preset value. When the ratio is not greater than the preset value, the partial structure of each low-grade raw wafer is removed and the surface of each low-grade raw wafer is smoothed. Finally, diode structures are formed in the smoothed low-grade raw wafers to obtain diode wafers.

### BACKGROUND OF THE INVENTION

### Field of the Invention

The invention relates to a method for fabricating wafers, particularly to methods for fabricating diode wafers and wafers to be processed.

### Description of the Related Art

In semiconductor manufacturing, wafers are sliced from ingots. Firstly, suitable materials are selected to create the ingots. The common materials include silicon and gallium arsenide. The selected material is placed in a high-temperature furnace for melting. The temperature and gas conditions in the furnace need to be properly controlled to ensure that the material melts uniformly to reach the required purity. In the molten material, a crystal called a “seed crystal” (usually single-crystal silicon) is gently inserted and slowly lifted. During the lifting process, the crystal captures the seed from the molten material to form a growing ingot. The ingot gradually cools during the pulling process, forming a single crystal structure. The cooling rate and temperature control during the process are critical for the quality of the ingot to ensure its purity and integrity. Once cooled, the ingot is sliced to form wafers of the desired diameter, typically using a diamond blade or other cutting tools. The sliced wafers are chemically or mechanically treated to remove surface residues, contaminants, and defects, making the surface smooth and clean. The wafers are then polished to further improve surface flatness and optical quality. Finally, the finished wafers are cleaned to remove any remaining residues and contaminants, followed by inspection and testing to ensure that they meet specific quality standards.

In the semiconductor industry, A-grade wafers and B-grade wafers are defined by wafer quality and specifications. These definitions are usually determined by negotiation among semiconductor manufacturers, international standards organizations, and customers. Generally, A-grade wafers have higher quality standards in areas such as surface flatness, thickness uniformity, and lattice structure integrity. B-grade wafers, having lower quality standards, are usually used for general applications that do not require very high performance and reliability. A-grade wafers have a lower defect density, meaning there are fewer defects on the wafer surface or within its volume. B-grade wafers may have a higher defect density, meaning there could be more defects on the wafer surface or within its volume. A-grade wafers have strict specifications for dimensions, thickness, flatness, and lattice orientation to ensure consistency and repeatability in the manufacturing process. In contrast, B-grade wafers have relatively looser specifications for dimensions, flatness, and lattice orientation compared to A-grade wafers. Generally, wafers to be processed are classified into low-grade, mid-grade, and high-grade wafers. However, the prices of higher-grade wafers are often not reduced in the market. For example, diode wafers include low-grade, mid-grade, and high-grade diode wafers. Due to pricing factors, many low-grade diode wafers are implemented with lower-quality A-grade wafers, resulting in poor quality. Moreover, many mid-grade diode wafers are implemented with higher-quality A-grade wafers. However, due to differences in substrate costs, the mid-grade diode wafers are unable to compete with low-mid-grade diode wafers.

To overcome the abovementioned problems, the present invention provides methods for fabricating diode wafers and wafers to be processed, so as to solve the afore-mentioned problems of the prior art.

### SUMMARY OF THE INVENTION

The invention provides methods for fabricating diode wafers and wafers to be processed, which fabricate diode wafers and wafers to be processed with better qualities at a lower cost.

In an embodiment of the invention, a method for fabricating diode wafers processes multiple raw wafers sliced from an ingot and includes: determining whether the multiple raw wafers meet a fabrication specification: if yes, using the raw wafer as a high-grade raw wafer; and if no, using the raw wafers as low-grade raw wafers; calculating the ratio of the number of the low-grade raw wafers with problems related to crystal oriented pits (COPs) to the number of all the low-grade raw wafers and determining whether the ratio is greater than a preset value: if yes, ending; and if no, removing the partial structure of each of the low-grade raw wafers, wherein the partial structure has a fixed thickness; smoothing the surface of each of the low-grade raw wafers whose structures are removed; and forming diode structures in each of the low-grade raw wafers that are smoothed to obtain the diode wafers.

In an embodiment of the invention, the items of the fabrication specification include resistance, defects, black film, color film, wafer thickness, wafer growth method, wafer size, wafer surface, concentration of metal particle residue, total thickness variation, total indicated reading (TIR), wafer warpage, site total indicated reading (STIR), and particle count.

In an embodiment of the invention, the defects include chipping, cracks, excess laser marking, scratches, stains, and lattice cracks.

In an embodiment of the invention, during the step of removing part of the structure from each low-grade original wafer, the low-grade raw wafers whose thickness is greater than a given value are selected and the partial structure of each of the low-grade raw wafers that are selected is removed.

In an embodiment of the invention, an etching process and a polishing process are sequentially performed on the surface of each of the low-grade raw wafers whose structures are removed to smooth the surface of each of the low-grade raw wafers whose structures are removed.

In an embodiment of the invention, a grinding process and a polishing process are sequentially performed on the surface of each of the low-grade raw wafers whose structures are removed to smooth the surface of each of the low-grade raw wafers whose structures are removed.

In an embodiment of the invention, the method for fabricating the diode wafers further includes a step of roughening the surface of each of the low-grade raw wafers that are smoothed. In the step of forming the diode structures in each of the low-grade raw wafers that are smoothed to obtain the diode wafers, the diode structures are formed in each of the low-grade raw wafers that are roughened to obtain the diode wafers.

In an embodiment of the invention, the surface of each of the low-grade raw wafers that are smoothed is roughened using a bench etching method or a spin etching method.

In an embodiment of the invention, the method for fabricating the diode wafers further includes a step of forming a conductive metal layer on each of the diode wafers.

In an embodiment of the invention, diode structure includes a doped well, a first heavily-doped area, and a second heavily-doped area. The doped well, having a first conductivity type, is formed in the low-grade raw wafer that is smoothed. The first heavily-doped area, having the first conductivity type, is formed in the doped well. The second heavily-doped area, having a second conductivity type opposite to the first conductivity type, is formed in the doped well.

In an embodiment of the invention, a method for fabricating wafers to be processed processes multiple raw wafers sliced from an ingot and includes: determining whether the raw wafers meet a fabrication specification: if yes, using the raw wafer as a high-grade raw wafer; and if no, using the raw wafers as low-grade raw wafers; calculating the ratio of the number of the low-grade raw wafers with problems related to crystal oriented pits (COPs) to the number of all the low-grade raw wafers and determining whether the ratio is greater than a preset value: if yes, ending; and if no, removing the partial structure of each of the low-grade raw wafers, wherein the partial structure has a fixed thickness; and smoothing the surface of each of the low-grade raw wafers whose structures are removed to obtain the wafers to be processed.

In an embodiment of the invention, the items of the fabrication specification include resistance, defects, black film, color film, wafer thickness, wafer growth method, wafer size, wafer surface, concentration of metal particle residue, total thickness variation, total indicated reading (TIR), wafer warpage, site total indicated reading (STIR), and particle count.

In an embodiment of the invention, the defects include chipping, cracks, excess laser marking, scratches, stains, and lattice cracks.

In an embodiment of the invention, during the step of removing part of the structure from each low-grade original wafer, the low-grade raw wafers whose thickness is greater than a given value are selected and the partial structure of each of the low-grade raw wafers that are selected is removed.

In an embodiment of the invention, an etching process and a polishing process are sequentially performed on the surface of each of the low-grade raw wafers whose structures are removed to smooth the surface of each of the low-grade raw wafers whose structures are removed.

In an embodiment of the invention, a grinding process and a polishing process are sequentially performed on the surface of each of the low-grade raw wafers whose structures are removed to smooth the surface of each of the low-grade raw wafers whose structures are removed.

In an embodiment of the invention, the method for fabricating the wafers further includes a step of roughening the surface of each of the low-grade raw wafers that are smoothed.

In an embodiment of the invention, the surface of each of the low-grade raw wafers that are smoothed is roughened using a bench etching method or a spin etching method.

To sum up, the methods for fabricating diode wafers and wafers to be processed select low-grade wafers with better qualities based on the existence of crystal oriented pits (COP), thereby fabricating diode wafers and wafers to be processed with better qualities at a lower cost.

Below, the embodiments are described in detail in cooperation with the drawings to make easily understood the technical contents, characteristics and accomplishments of the invention.

### BRIEF DESCRIPTION OF THE DRAWINGS

FIG. 1 is a flowchart of a method for fabricating diode wafers according to an embodiment of the invention;

FIG. 2 is a cross-sectional view of a diode wafer according to an embodiment of the invention; and

FIG. 3 is a flowchart of a method for fabricating wafers to be processed according to an embodiment of the invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express what the embodiment in the invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Certain terms are used throughout the description and the claims to refer to particular components. One skilled in the art appreciates that a component may be referred to using different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to encompass any indirect or direct connection. Accordingly, if this disclosure mentions that a first device is coupled with a second device, it means that the first device may be directly or indirectly connected to the second device through electrical connections, wireless communications, optical communications, or other signal connections with/without other intermediate devices or connection means.

Certain terms are used throughout the description and the claims to refer to particular components. One skilled in the art appreciates that a component may be referred to using different names. This disclosure does not intend to distinguish between components that differ in name but in function. In the description and in the claims, the term “comprise” is used in an open-ended fashion, and thus should be interpreted to mean “include, but not limited to.” The phrases “be coupled to,” “couples to,” and “coupling to” are intended to encompass any indirect or direct connection.

Accordingly, if this disclosure mentions that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

Throughout the description and claims, it will be understood that when a component is referred to as being “positioned on,” “positioned above,” “connected to,” “engaged with,” or “coupled with” another component, it can be directly on, directly connected to, or directly engaged with the other component, or intervening component may be present. In contrast, when a component is referred to as being “directly on,” “directly connected to,” or “directly engaged with” another component, there are no intervening components present.

In the following description, methods for fabricating diode wafers and wafers to be processed will be provided, which select low-grade wafers with better qualities based on the existence of crystal oriented pits (COPs), thereby fabricating diode wafers and wafers to be processed with better qualities at a lower cost.

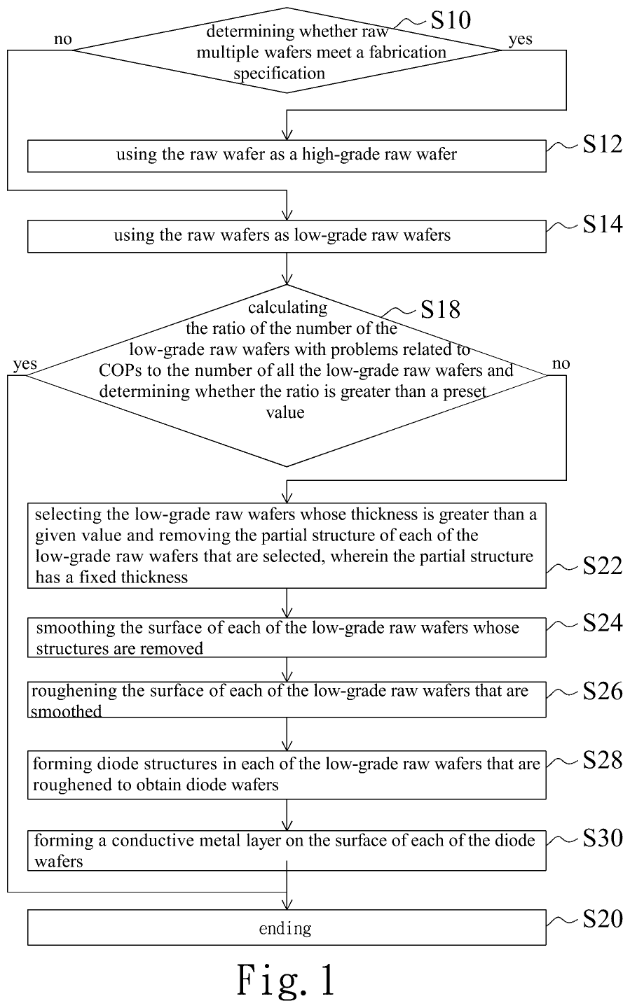

FIG. 1 is a flowchart of a method for fabricating diode wafers according to an embodiment of the invention. Referring to FIG. 1, the method for fabricating diode wafers will be introduced as follows, which processes raw wafers sliced from an ingot. These wafers have been ground, etched, and polished to smooth their surfaces. The raw wafers are exemplified by silicon wafers, but the invention is not limited thereto. Firstly, in Step S10, it is determined that the multiple raw wafers meet a fabrication specification. When the raw wafer meets the fabrication specification, the raw wafer is used as a high-grade wafer as shown in Step S12. When the raw wafer does not meet the fabrication specification, the raw wafer is used as a low-grade wafer as shown in Step S14. For example, the items of the fabrication specification may include, but are not limited to, resistance, defects, black film, color film, wafer thickness, wafer growth method, wafer size, wafer surface, concentration of metal particle residue, total thickness variation, total indicated reading (TIR), wafer warpage, site total indicated reading (STIR), and particle count. The defects may include chipping, cracks, excess laser marking, scratches, stains, and lattice cracks, but the invention is not limited thereto. The total thickness variation (TTV) is defined as the difference between the maximum and minimum thickness of a wafer when clamped tightly against a reference plane; it is generally expressed in micrometers (μm), typically represented as ≤15 μm. The total indicated reading (TIR) is defined as the difference between the maximum and minimum distances between the wafer surface and a reference plane formed by the smallest plane of all points' intercepts within the qualified area of the wafer surface when the wafer is tightly clamped. Wafer warpage is defined as the difference between the maximum and minimum distances between the wafer surface and a reference plane (usually using the back surface of the wafer as the reference plane) when the wafer is not tightly clamped. Wafer warpage includes both concave and convex cases, where concave warpage is negative, and convex warpage is positive; it is generally expressed in micrometers (typically represented as ≤30 μm). The site total indicated reading (STIR) is defined as the difference between the maximum and minimum distances between the wafer surface and a reference plane formed by the smallest plane of all points' intercepts within a specified local area of the wafer surface when the wafer is tightly clamped. Table 1 provides a manufacturing specification. If the raw wafer does not meet any one of the conditions in the manufacturing specification, it is considered a low-grade raw wafer. If the raw wafer meets all the conditions in the manufacturing specification, it is considered a high-grade raw wafer. Additionally, if any defects, black films, or color films are observed on the raw wafer, it is also considered a low-grade original wafer. If no defects, black films, or color films are observed on the raw wafer, it is considered a high-grade raw wafer.

TABLE 1

| | 6-inch wafer | 8-inch wafer | 12-inch wafer |
|---|---|---|---|
| Crystal growth | Czochralski method | | |
| method of wafer | | | |
| Wafer thickness | 625 ± 15 μm | 725 ± 25 μm | 750 ± 25 μm |
| Wafer size— | 150 mm | 200 mm | 300 mm |
| expressed by | | | |
| diameter | | | |
| Wafer surface | Single-side | Single-side | Double-side |
| | polished (shiny | polished (shiny | polished |
| | surface) | surface) | (double shiny |
| | Single-side | Single-side | surface) |
| | roughened | roughened | |
| | (matte surface | (matte surface) | |

| | |
|---|---|
| Concentration of | <5¹⁰/cm² |
| Na metal particle | |
| residue | |
| Concentration of | <5¹⁰/cm² |
| Al metal particle | |
| residue | |
| Concentration of | <5¹⁰/cm² |
| Fe metal particle | |
| residue | |
| Concentration of | <5¹⁰/cm² |
| Ni metal particle | |
| residue | |
| Concentration of | <5¹⁰/cm² |
| Cr metal particle | |
| residue | |
| Concentration of | <5¹⁰/cm² |
| Cu metal particle | |
| residue | |
| Concentration of | <5¹⁰/cm² |
| Zn metal particle | |
| residue | |
| Concentration of | <5¹⁰/cm² |
| Ca metal particle | |
| residue | |
| TTV | Maximum 7 μm |
| TIR | ≤4 μm |
| Wafer warpage | Maximum 50 μm |
| STIR | <1.5 μm |
| Particle count | |
| ≥0.3 um | <20 |
| ≥0.2 um | <30 |
| resistance | 10⁻⁴~10⁻³ Ω · cm |

In general, there are low-grade raw wafers sliced from the ingot. After Step S14 Step S18 is performed. In Step S18, the ratio of the number of the low-grade raw wafers with problems related to crystal oriented pits (COPs) to the number of all the low-grade raw wafers is calculated and it is determined whether the ratio is greater than a preset value. Crystal oriented pits are difficultly removed in etching, grinding, or polishing processes. They can be observed using tools such as optical microscopes or electron microscopes. The problems related to COPs are defined as the failure of corresponding low-grade raw wafers to pass the COP specification inspection set by the detection equipment. For example, if the number of lattice orientation pits on a low-grade raw wafer exceeds a preset value, the wafer will fail the COP specification inspection set by the detection equipment. If the number of selected low-grade raw wafers with problems related to COPs is 64 and the total number of selected low-grade raw wafers is 100, the ratio is 0.64. The presence of COPs indicates the occurrence of undesired holes when fabricating diodes and etching wafers. During the diode fabricating process, silicon wafers are used as substrates for processes like ion implantation or diffusion. If holes appear in some area, there will be no silicon wafer present in these areas. Therefore, it cannot support the required processes, leading to electrical characteristic drift in the diodes, resulting in defects that decrease the yield. Additionally, during the diode fabricating process, it may be necessary to dig holes and fill them with the required materials. If the COPs are bad, excessive particle may cause problems in subsequent processes, leading to electrical characteristic drift in the diode itself and resulting in defects and decreased yield. Therefore, high-quality silicon wafers help prevent yield reduction due to material issues. In other words, if the ratio of the selected low-grade raw wafers with problems related COPs to the total number of the selected low-grade raw wafers is greater than the preset value, the yield of diode wafers produced from this batch of low-grade raw wafers will significantly decrease. Thus, Step S20 is performed, which ends the entire process. Conversely, if the ratio of the selected low-grade raw wafers with problems related to COPs to the total number of the selected low-grade raw wafers is not greater than the preset value, the yield of diode wafers produced from this batch of low-grade raw wafers will significantly increase, and the low price of low-grade raw wafers will be highly valuable in the market. In other words, if the result of Step S18 is no, the process proceeds to Step S22. In Step S22, the low-grade raw wafers whose thickness is greater than a given value are selected and the partial structure of each of the low-grade raw wafers that are selected is removed. The partial structure has a fixed thickness used to remove the observed COPs. The fixed thickness depends on how deep the observed COPs are located. For example, if the observed COPs are located at a depth of 7 micrometers from the surface, the fixed thickness can be 7 micrometers.

After Step S22, Step S24 is performed. In Step S24, the surface of each low-grade raw wafer whose structure is smoothed to remove surface stains, chemical films, or scratches to ensure that the surface flatness and the particle number of the low-grade raw wafer meet the required standards. In some embodiments of the invention, an etching process and a polishing process are sequentially performed on the surface of each of the low-grade raw wafers whose structures are removed to smooth the surface of each of the low-grade raw wafers whose structures are removed. Alternatively, a grinding process and a polishing process are sequentially performed on the surface of each of the low-grade raw wafers whose structures are removed to smooth the surface of each of the low-grade raw wafers whose structures are removed.

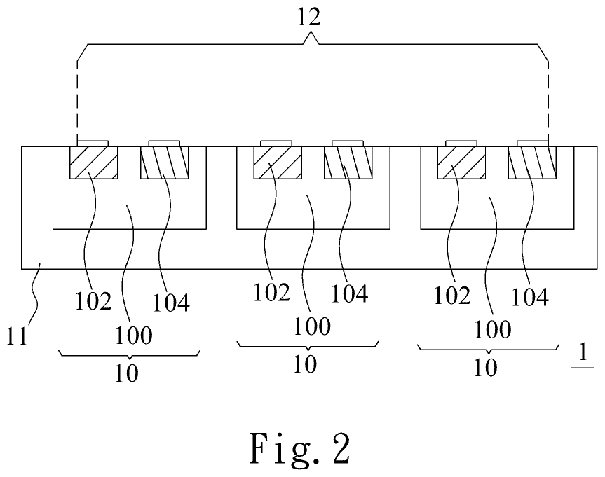

After Step S24, Step S26 is performed. In Step S26, the surface of each of the low-grade raw wafers that are smoothed is roughened to favor the stability of the connecting metal layer. The surface of each of the low-grade raw wafers that are smoothed may be roughened using a bench etching method or a spin etching method. Then, in Step S28, diode structures are formed in each of the low-grade raw wafers that are roughened to obtain diode wafers. Finally, in Step S30, a conductive metal layer is formed on each of the diode wafers and used as the electrode of the diode. After Step S30, the process proceeds to Step 20. Provided that substantially the same result is achieved, the steps of the flowchart shown in FIG. 1 need not be in the exact order shown and need not be contiguous, that is, other steps can be intermediate. FIG. 2 is a cross-sectional view of a diode wafer according to an embodiment of the invention. As illustrated in FIG. 2, each diode structure 10 may includes a doped well 100, a first heavily-doped area 102, and a second heavily-doped area 104. The doped well 100 and the first heavily-doped area 102 have a first conductivity type and the second heavily-doped area 104 has a second conductivity opposite to the first conductivity type. For example, when the first conductivity type is an N type, the second conductivity type is a P type. When the second conductivity type is an N type, the first conductivity type is a P type. The doped well 100 is formed in the low-grade raw wafer 11 that is roughened. The first heavily-doped area 102 and the second heavily-doped area 104 are formed in the doped well 100. A conductive metal layer is formed on the surface of the low-grade raw wafer that is roughened.

In the flowchart of FIG. 1, the step of selecting the low-grade raw wafers whose thickness is greater than the given value can be omitted. Thus, in Step S22, the partial structure of each of the low-grade raw wafers is removed. Besides, Step S26 can be also omitted. When Step S26 is omitted, diode structures are formed in each of the low-grade raw wafers that are smoothed to obtain diode wafers. Step S30 can be performed or omitted according to requirements. When Step S30 is omitted and after Step S28, Step S20 is directly performed.

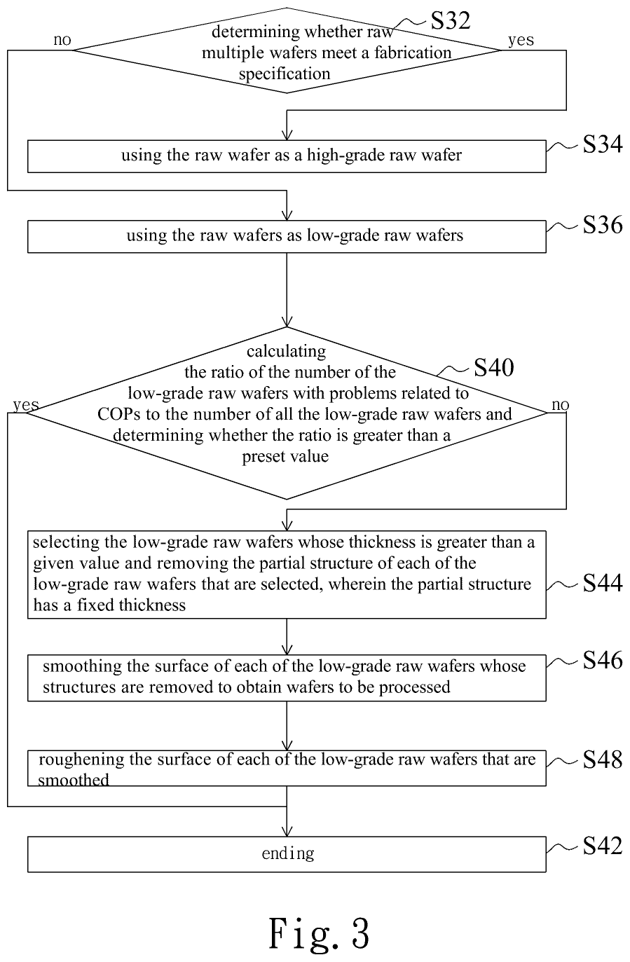

FIG. 3 is a flowchart of a method for fabricating wafers to be processed according to an embodiment of the invention. Referring to FIG. 3 the method for fabricating wafers to be processed will be introduced as follows. The method processes raw wafers sliced from an ingot. These wafers have been ground, etched, and polished to smooth their surfaces. The raw wafers are exemplified by silicon wafers, but the invention is not limited thereto. Steps S32, S34, S36, S40, S42, and S44 in FIG. 3 are respectively the same to Steps S10, S12, S14, S18, S20, and S22, so they will not be reiterated. After Step S44, Step S46 is performed. In Step S46, the surface of each of the low-grade raw wafers whose structures are removed is smoothed to obtain the wafers to be processed. Any semiconductor devices such as diodes or micro electro mechanical systems (MEMS) devices are formed in the wafers to be processed. In Step S46, an etching process and a polishing process are sequentially performed on the surface of each of the low-grade raw wafers whose structures are removed to smooth the surface of each of the low-grade raw wafers whose structures are removed. Alternatively, a grinding process and a polishing process are sequentially performed on the surface of each of the low-grade raw wafers whose structures are removed to smooth the surface of each of the low-grade raw wafers whose structures are removed. Then, in Step S48, the surface of each of the low-grade raw wafers that are smoothed is roughened to favor the stability of the connecting metal layer. The surface of each of the low-grade raw wafers that are smoothed is roughened using a bench etching method or a spin etching method. After Step S48, Step S42 is performed.

In the flowchart of FIG. 3, the step of selecting the low-grade raw wafers whose thickness is greater than the given value can be omitted. Thus, in Step S44, the partial structure of each of the low-grade raw wafers is removed. Besides, Step S48 can be performed or omitted according to requirements. When Step S48 is omitted and after Step S46, Step S42 is directly performed.

According to the embodiments provided above, the methods for fabricating diode wafers and wafers to be processed select low-grade wafers with better qualities based on the existence of crystal oriented pits, thereby fabricating diode wafers and wafers to be processed with better qualities at a lower cost.

The embodiments described above are only to exemplify the invention but not to limit the scope of the invention. Therefore, any equivalent modification or variation according to the shapes, structures, features, or spirit disclosed by the invention is to be also included within the scope of the invention.

What is claimed is:

1. A method for fabricating diode wafers, processing raw wafers sliced from an ingot and comprising:
determining whether the raw wafers meet a fabrication specification:
if yes, using the raw wafer as a high-grade raw wafer; and
if no, using the raw wafers as low-grade raw wafers;
calculating a ratio of number of the low-grade raw wafers with problems related to crystal oriented pits (COPs) to number of all the low-grade raw wafers and determining whether the ratio is greater than a preset value:
if yes, ending; and
if no, removing a partial structure of each of the low-grade raw wafers, wherein the partial structure has a fixed thickness;
smoothing a surface of each of the low-grade raw wafers whose structures are removed; and
forming diode structures in each of the low-grade raw wafers that are smoothed to obtain the diode wafers.

2. The method for fabricating the diode wafers according to claim 1, wherein items of the fabrication specification include resistance, defects, black film, color film, wafer thickness, wafer growth method, wafer size, wafer surface, concentration of metal particle residue, total thickness variation, total indicated reading (TIR), wafer warpage, site total indicated reading (STIR), and particle count.

3. The method for fabricating the diode wafers according to claim 2, wherein the defects include chipping, cracks, excess laser marking, scratches, stains, and lattice cracks.

4. The method for fabricating the diode wafers according to claim 1, wherein in the step of removing the partial structure of each of the low-grade raw wafers, the low-grade raw wafers whose thickness is greater than a given value are selected and the partial structure of each of the low-grade raw wafers that are selected is removed.

5. The method for fabricating the diode wafers according to claim 1, wherein in the step of smoothing the surface of each of the low-grade raw wafers whose structures are removed, an etching process and a polishing process are sequentially performed on the surface of each of the low-grade raw wafers whose structures are removed to smooth the surface of each of the low-grade raw wafers whose structures are removed.

6. The method for fabricating the diode wafers according to claim 1, wherein in the step of smoothing the surface of each of the low-grade raw wafers whose structures are removed, a grinding process and a polishing process are sequentially performed on the surface of each of the low-grade raw wafers whose structures are removed to smooth the surface of each of the low-grade raw wafers whose structures are removed.

7. The method for fabricating the diode wafers according to claim 1, further comprising a step of roughening the surface of each of the low-grade raw wafers that are smoothed, and in the step of forming the diode structures in each of the low-grade raw wafers that are smoothed to obtain the diode wafers, the diode structures are formed in each of the low-grade raw wafers that are roughened to obtain the diode wafers.

8. The method for fabricating the diode wafers according to claim 7, wherein the surface of each of the low-grade raw wafers that are smoothed is roughened using a bench etching method or a spin etching method.

9. The method for fabricating the diode wafers according to claim 7, further comprising a step of forming a conductive metal layer on each of the diode wafers.

10. The method for fabricating the diode wafers according to claim 1, wherein the diode structure includes:
a doped well, having a first conductivity type, formed in the low-grade raw wafer that is smoothed;
a first heavily-doped area, having the first conductivity type, formed in the doped well; and
a second heavily-doped area, having a second conductivity type opposite to the first conductivity type, formed in the doped well.

11. A method for fabricating wafers to be processed, processing raw wafers sliced from an ingot and comprising:
determining whether the raw wafers meet a fabrication specification:
if yes, using the raw wafer as a high-grade raw wafer; and
if no, using the raw wafers as low-grade raw wafers;
calculating a ratio of number of the low-grade raw wafers with problems related to crystal oriented pits (COPs) to number of all the low-grade raw wafers and determining whether the ratio is greater than a preset value:
if yes, ending; and
if no, removing a partial structure of each of the low-grade raw wafers, wherein the partial structure has a fixed thickness; and
smoothing a surface of each of the low-grade raw wafers whose structures are removed to obtain the wafers to be processed.

12. The method for fabricating the wafers to be processed according to claim 11, wherein items of the fabrication specification include resistance, defects, black film, color film, wafer thickness, wafer growth method, wafer size, wafer surface, concentration of metal particle residue, total thickness variation, total indicated reading (TIR), wafer warpage, site total indicated reading (STIR), and particle count.

13. The method for fabricating the wafers to be processed according to claim 12, wherein the defects include chipping, cracks, excess laser marking, scratches, stains, and lattice cracks.

14. The method for fabricating the wafers to be processed according to claim 11, wherein in the step of removing the partial structure of each of the low-grade raw wafers, the low-grade raw wafers whose thickness is greater than a given value are selected and the partial structure of each of the low-grade raw wafers that are selected is removed.

15. The method for fabricating the wafers to be processed according to claim 11, wherein in the step of smoothing the surface of each of the low-grade raw wafers whose structures are removed, an etching process and a polishing process are sequentially performed on the surface of each of the low-grade raw wafers whose structures are removed to smooth the surface of each of the low-grade raw wafers whose structures are removed.

16. The method for fabricating the wafers to be processed according to claim 11, wherein in the step of smoothing the surface of each of the low-grade raw wafers whose structures are removed, a grinding process and a polishing process are sequentially performed on the surface of each of the low-grade raw wafers whose structures are removed to smooth the surface of each of the low-grade raw wafers whose structures are removed.

17. The method for fabricating the wafers to be processed according to claim 11, further comprising a step of roughening the surface of each of the low-grade raw wafers that are smoothed.

18. The method for fabricating the wafers to be processed according to claim 17, wherein the surface of each of the low-grade raw wafers that are smoothed is roughened using a bench etching method or a spin etching method.
